(19) United States
(12) Patent Application Publication
(10) Pub. No.: US 2015/0014719 A1
(43) Pub. Date: Jan. 15, 2015

(54) LIGHT-EMITTING DIODE CHIP

(71) Applicant: INDUSTRIAL TECHNOLOGY RESEARCH INSTITUTE, Hsinchu (TW)

(72) Inventors: Chih-Sheng JAO, Bade City (TW); Wen-Hua ZHANG, Zhudong Township (TW); Dar-Weei SHYU, Zhudong Township (TW); Meng-Chi HUANG, Zhongli City (TW); Yao-Chi PENG, Hsinchu City (TW)

(73) Assignee: INDUSTRIAL TECHNOLOGY RESEARCH INSTITUTE, Hsinchu (TW)

(21) Appl. No.: 14/086,774

(22) Filed: Nov. 21, 2013

(30) Foreign Application Priority Data
Jul. 15, 2013 (TW) 102125315

(51) Int. Cl. H01L 33/50

(52) U.S. Cl. CPC H01L 33/504
USPC 257/98

(57) ABSTRACT

A light-emitting diode chip includes an illuminating body and a first phosphor layer. The first phosphor layer is disposed on the illuminating body, and the first phosphor layer includes multiple first phosphor powder groups and multiple second phosphor powder groups. The illuminating body has a first emission wavelength, the first phosphor powder groups have a second emission wavelength, and the second phosphor powder groups have a third emission wavelength. The first wavelength is smaller than the second emission wavelength, and the second emission wavelength is smaller than the third emission wavelength.

### CROSS-REFERENCE TO RELATED APPLICATIONS

This non-provisional application claims priority under 35 U.S.C. §119(a) on Patent Application No(s). 102125315 filed in Taiwan, R.O.C. on Jul. 15, 2013, the entire contents of which are hereby incorporated by reference.

### TECHNICAL FIELD

The disclosure relates to a light-emitting diode chip.

### BACKGROUND

With the development of technologies, light-emitting diodes have become the main illuminating devices. At this present time, the color rendering index of white light-emitting diodes is about 70. However, the color rendering index is not high enough for many applications. For example, in indoor illuminating, medical illuminating, art illuminating, greenhouse illuminating, or in other applications, the color rendering index of white light-emitting diodes needs to be improved.

In general, in order to improve the color rendering index of the white light-emitting diodes, a plurality of phosphor powders are mixed in capsules, so that the mixed phosphor powders emit light that may cover the spectrum of visible light. Thus, the color rendering index of the white light-emitting diode is increased greatly, and the color rendering index of the white light-emitting diode is greater than 80. Therefore, the white light-emitting diodes can be used in many fields of illuminating.

However, the white light-emitting diodes still need to be improved. Since a plurality of phosphor powders with different emission wavelengths is mixed together, the light, emitted by one of the phosphor powders, is absorbed by the other phosphor powders easily, and the other phosphor powders are excited again. Therefore, the white light-emitting diodes manufactured by mixing process have the problem of secondary excitation between the two kinds of phosphor powders. Luminous efficacy of the white light-emitting diodes is decreased by at least 15% because of the secondary excitation between the two kinds of phosphor powders.

In other words, although the color rendering index of the white light-emitting diodes manufactured by the mixing process is improved, the mixing process also reduces the luminous efficacy of the white light light-emitting diodes.

### SUMMARY

According to an embodiment, a light-emitting diode chip is disclosed. The light-emitting diode chip comprises an illuminating body and a first phosphor layer. The illuminating body has a first emission wavelength. The first phosphor layer is disposed on the illuminating body. The first phosphor layer comprises a plurality of first phosphor powder groups and a plurality of second phosphor powder groups. The first phosphor powder groups have a second emission wavelength, and the second phosphor powder groups have a third emission wavelength. The first wavelength is smaller than the second emission wavelength, and the second emission wavelength is smaller than the third emission wavelength.

According to another embodiment, a light-emitting diode chip is disclosed. The light-emitting diode chip comprises an illuminating body, a phosphor layer, and a plurality of second phosphor powder groups. The illuminating body has a first emission wavelength. The phosphor layer is disposed on the illuminating body. The phosphor layer has a plurality of first phosphor powder groups. The first phosphor powder groups of the phosphor layer have a second emission wavelength. The second phosphor powder groups are disposed on the phosphor layer separately. The second phosphor powder groups have a third emission wavelength. The first wavelength is smaller than the second emission wavelength, and the second emission wavelength is smaller than the third emission wavelength.

### BRIEF DESCRIPTION OF THE DRAWINGS

The present disclosure will become more fully understood from the detailed description given herein below for illustration, thus does not limit the present disclosure, wherein:

FIG. 1A is a perspective view of part of the light-emitting diode chip according to an embodiment of the disclosure;

FIG. 1B is a perspective view of part of the light-emitting diode chip according to another embodiment of the disclosure;

FIG. 1C is a schematic diagram of the optical paths of the phosphor powder groups in FIG. 1A;

FIG. 1D is a schematic diagram of the first phosphor powder groups in FIG. 1A;

FIG. 1E is a schematic diagram of the second phosphor powder groups in FIG. 1A;

FIG. 2A is a graph of the relationship between luminous efficacy and the wavelength of the light-emitting diode chip according to an embodiment of the disclosure;

FIG. 2B is a graph of the relationship between luminous efficacy and the wavelength of the light-emitting diode chip according to Comparative Example 1 of the disclosure;

FIG. 2C is a graph of the relationship between luminous efficacy and the wavelength of the light-emitting diode chip according to Comparative Example 2 of the disclosure;

FIG. 2D is a graph of the relationship between luminous efficacy and the wavelength of the light-emitting diode chip according to Comparative Example 3 of the disclosure;

FIG. 3 is a perspective view of part of the light-emitting diode chip according to another embodiment of the disclosure;

FIG. 4 is a perspective view of part of the light-emitting diode chip according to another embodiment of the disclosure;

FIG. 5A is a perspective view of part of the light-emitting diode chip according to another embodiment of the disclosure;

FIG. 5B is a perspective view of part of the light-emitting diode chip according to another embodiment of the disclosure;

FIG. 6A is a perspective view of part of the light-emitting diode chip according to another embodiment of the disclosure;

FIG. 6B is a schematic diagram of the first phosphor powder groups in FIG. 6A.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

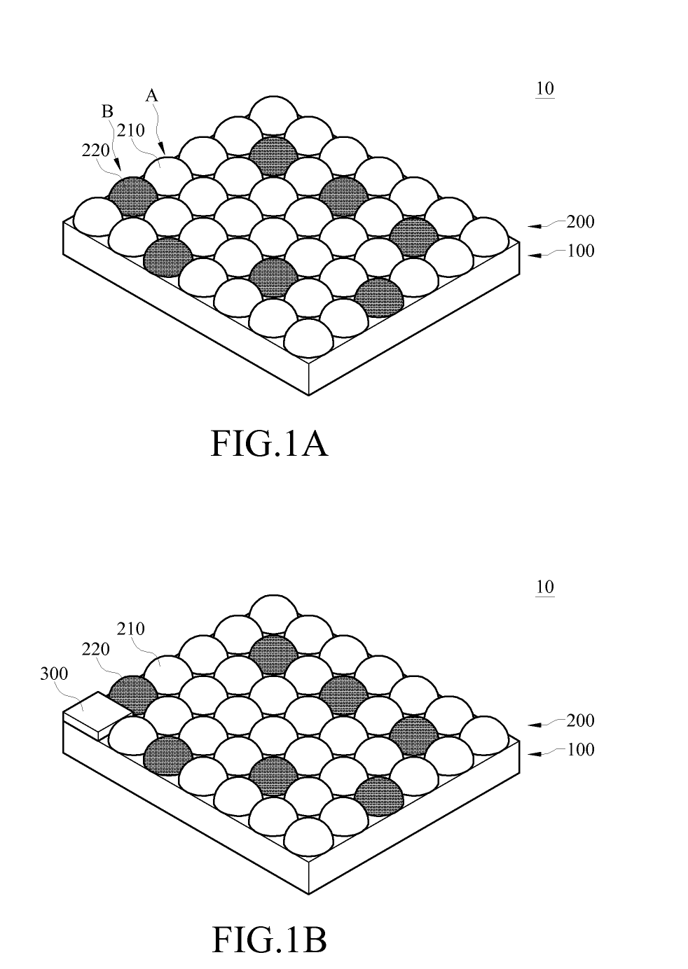

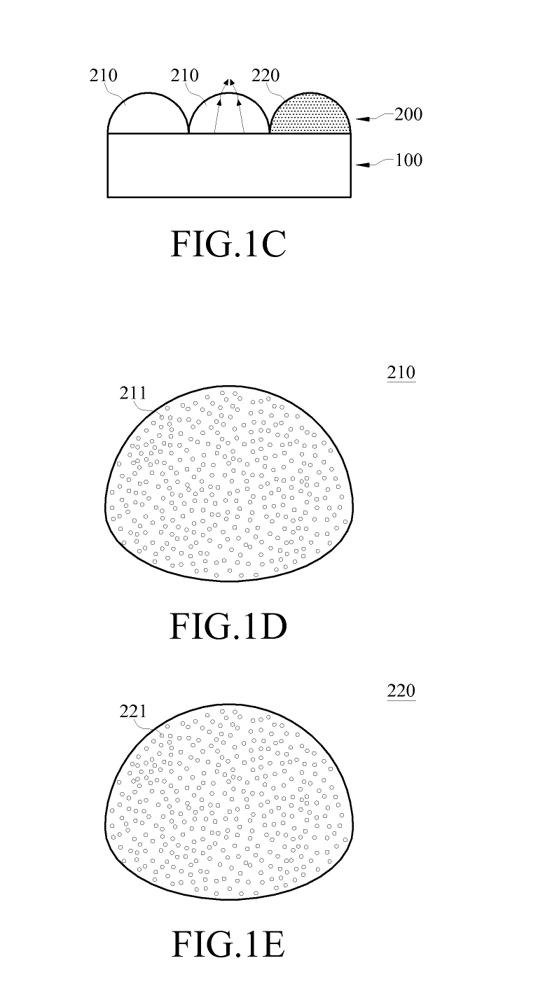

First, please refer to FIGS. 1A to 1C, FIG. 1A is a perspective view of part of the light-emitting diode chip according to an embodiment of the disclosure, FIG. 1B is a perspective view of part of the light-emitting diode chip according to another embodiment of the disclosure, and FIG. 1C is a schematic diagram of the optical paths of the phosphor powder groups in FIG. 1A. In the disclosure, a light-emitting diode chip represents the structure which phosphor powder groups are disposed on a light-emitting die, and a package structure represents the structure of the light-emitting diode chip after a packaging process.

As shown in FIG. 1A, a light-emitting diode chip 10 comprises an illuminating body 100 and a first phosphor layer 200. The first phosphor layer 200 is disposed on the illuminating body 100. The first phosphor layer 200 comprises a plurality of first phosphor powder groups 210 and a plurality of second phosphor powder groups 220. The first phosphor powder groups 210 are independent of each other. Similarly, the second phosphor powder groups 220 are independent of each other.

In this embodiment, the light-emitting diode chip 10 comprises at least one electrode 300, disposed on the illuminating body 100 (as shown in FIG. 1B). Thereby, the electrode 300 is taken as an electrical contact of the light-emitting diode chip 10, so that the illuminating body 100 is electrically connected to external circuits through the electrode 300.

The illuminating body 100 has a first emission wavelength. The first phosphor powder groups 210 have a second emission wavelength, and the second phosphor powder groups 220 have a third emission wavelength. The first emission wavelength is smaller than the second emission wavelength, and the second emission wavelength is smaller than the third emission wavelength. For example, the illuminating body 100 is a blue chip and is capable of emitting blue light. The first phosphor powder groups 210 are, for example, yellow phosphor powder groups and are capable of emitting yellow light after absorbing energy (e.g. photon). The second phosphor powder groups 220 are, for example, red phosphor powder groups and are capable of emitting red light after absorbing energy (e.g. photon).

In this embodiment and some other embodiments, the spectrum of the light emitted by the illuminating body 100, the first phosphor powder groups 210, and the second phosphor powder groups 220 are, for example, continuous spectrums. In other words, each spectrum of the light emitted by the illuminating body 100, the first phosphor powder groups 210 and the second phosphor powder groups 220 cover different wavelengths. The first emitting wavelength represents the wavelength having the greatest illuminating power among the spectrum of the light emitted by the illuminating body 100. The second emitting wavelength represents the wavelength having the greatest illuminating power among the spectrum of the light emitted by the first phosphor powder groups 210. The third emitting wavelength represents the wavelength having the greatest illuminating power among the spectrum of the light emitted by the second phosphor powder groups 220.

The following context further describes the light-emitting diode chips. In this embodiment (as FIG. 1C), the first phosphor powder groups 210 and the second phosphor powder groups 220 of the first phosphor layer 200 directly contact with the illuminating body 100. Also, the first phosphor powder groups 210 and the second phosphor powder groups 220 do not overlap each other. Therefore, when the phosphor powder groups illuminate light, the light emitted by different colors of the phosphor powder groups do not pass through other phosphor powder groups, such that the loss of the luminous efficacy due to the secondary excitation is greatly reduced or avoided.

Moreover, the first phosphor powder groups 210 of the first phosphor layer 200 have a plurality of first emitting sections A (as shown in FIG. 1A), and the second phosphor powder groups 220 of the first phosphor layer 200 have a plurality of second emitting sections B (as shown in FIG. 1A). The first emitting sections A and the second emitting sections B are arranged in an array arrangement on the illuminating body 100. Thus, when the light emitted by the illuminating body 100 passes through the first phosphor powder groups 210 and the second phosphor powder groups 220, the first phosphor powder groups 210 and the second phosphor powder groups 220 emit corresponding light, respectively. Therefore, the light emitted by the illuminating body 100, the first phosphor powder groups 210, and the second phosphor powder groups 220 achieves the effect of mixing light.

In this embodiment, the light body 100 emits blue light, the first phosphor powder groups 210 emit yellow light, and the second phosphor powder groups 220 emit red light. By mixing the three kinds of light, the light-emitting diode chip 10 is capable of emitting white light. As compared with previous art, the color rendering index of the light-emitting diode chip 10 is improved.

In this and some other embodiments, the first emitting sections A of the first phosphor powder groups 210 and the second emitting sections B of the second phosphor powder groups 220 are evenly distributed on the illuminating body 100 so as to improve the luminous quality of the light-emitting diode chip 10. For instance, when the arrangement of the second phosphor powder groups 220 is too concentrated on some positions of the illuminating body 100, light mixing ability of the positions of the light-emitting diode chip 10 is decreased, so that the luminous quality of the light-emitting diode chip is lowered.

Also, the plurality of first phosphor powder groups 210 of the first phosphor layer 200 have a first emitting area, and the plurality of second phosphor powder groups 220 of the first phosphor layer 200 have a second emitting area. The first emitting area represents the summation of the emitting area of the plurality of first phosphor powder groups 210. The second emitting area represents the summation of the emitting area of the plurality of second phosphor powder groups 220. In this embodiment, each of the first phosphor powder groups 210 and each of the second phosphor powder groups 220 have the same or similar emitting areas. Thus, in FIG. 1A, symbols representing the first phosphor powder groups 210 and the second phosphor powder groups 220 have the same or similar sizes.

In this and some other embodiments, the size of each of the first phosphor powder groups 210 and the size of each of the second phosphor powder groups 220 correspond to the size of the illuminating body 100 and the size of the manufactured light-emitting diode chip 10. In other words, the size of the first phosphor powder groups 210 and the second phosphor powder groups 220 are adjusted according to the size of the illuminating body 100 and the manufactured light-emitting diode chip 10. In this embodiment, the size of each of the first phosphor powder groups 210 and the size of each of the second phosphor powder groups 220 are between 20 μm and 500 μm (namely, the size represents the width or the length of the first phosphor powder groups 210 and the second phosphor powder groups 220). In some embodiments, the size of each of the first phosphor powder groups 210 and the size of each of the second phosphor powder groups 220 are between 25 μm and 450 μm. For instance, the size of each of the first phosphor powder groups 210 and the size of each of the second phosphor powder groups 220 are 30 μm, 40 μm, 50 μm, 60 μm, 70 μm, 80 μm, 90 μm, 100 μm, 150 μm, 200 μm, 300 μm, or 400 μm, but the disclosure is not limited thereto.

In this embodiment, the ratio of the first emitting area of the first phosphor powder groups 210 to the second emitting area of the second phosphor powder groups 220 is between 5:1 and 20:1. A user can adjust the ratio of the first emitting area to the second emitting area according to his/her needs (e.g. improving the color rendering index, or improving the luminous efficacy). For example, the ratio of the first emitting area to the second emitting area can be adjusted as 8:1, 10:1, 12:1, 15:1, or 18:1 . . . .

However, each of the first phosphor powder groups 210 and the second phosphor powder groups 220 having the same or similar emitting areas does not limit the disclosure. In some other embodiments, each of the first phosphor powder groups 210 and the second phosphor powder groups 220 have obvious different emitting areas. However, in those embodiments, the ratio of the first emitting area of the first phosphor powder groups 210 to the second emitting area of the second phosphor powder groups 220 is still between 5:1 and 20:1.

The following further describes the first phosphor powder groups and the second phosphor powder groups. Please refer to FIGS. 1C to 1E, FIG. 1C is a schematic diagram of the optical paths of the phosphor powder groups in FIG. 1A, FIG. 1D is a schematic diagram of the first phosphor powder groups in FIG. 1A, and FIG. 1E is a schematic diagram of the second phosphor powder groups in FIG. 1A.

In this embodiment, the side of the plurality of first phosphor powder groups 210 of the first phosphor layer 200, which does not contact with the illuminating body 100, is a curved surface. Also, the side of the second phosphor powder groups of the first phosphor layer 200, which does not contact with the illuminating body 100, is a curved surface. In this embodiment, the first phosphor powder groups 210 have a contacting surface, and the contacting surface of the first phosphor powder groups 210 contacts with the illuminating body 100. Also, the second phosphor powder groups 220 have a contacting surface, and the contacting surface of the second phosphor powder groups 220 contacts with the illuminating body 100. The side opposite to the contacting surface of the first phosphor powder groups 210 is a curved surface, and the side opposite to the contacting surface of the second phosphor powder groups 220 is a curved surface. Further, in this embodiment, the first phosphor powder groups 210 and the second phosphor powder groups 220 are hemispherically-shaped. In detail, since the first phosphor powder groups 210 and the second phosphor powder groups 220 have curved surfaces, the curved surfaces can focus light better. Therefore, as the first phosphor powder groups 210 and the second phosphor powder groups 220 emit light, the light passing through other adjacent phosphor powder groups is decreased or is even avoided. Therefore, the secondary excitation of the light-emitting diode chip 10 is decreased or is even avoided since the hemispherical phosphor powder groups can focus light better. Thus, the luminous efficacy of the light-emitting diode chip 10 is further improved. The schematic diagram of the optical paths of the phosphor powder groups is described in FIG. 1C.

Furthermore, the first phosphor powder groups 210 have a plurality of first phosphorous granules 211 and, for example, an adhesive agent. Also, the second phosphor powder groups 220 have a plurality of second phosphorous granules 221 and, for example, an adhesive agent. The adhesive agent can shape the first phosphorous granules 211 and the second phosphorous granules 221 so as to strengthen the structure of the first phosphor powder groups 210 and the second phosphor powder groups 220. Furthermore, the adhesive agent can stick the first phosphor powder groups 210 and the second phosphor powder groups 220 on the illuminating body 100. In this and some other embodiments, as shown FIG. 1D, the emitting wavelength of each of the first phosphorous granules 211 is the same or similar. In other words, the first phosphor powder groups 210 comprising the plurality of first phosphorous granules 211 should be considered as a light source with a single color (the first phosphor powder groups 210 are pure light sources). Similarly, the emitting wavelength of each of the second phosphorous granules 221 is the same or similar. In other words, the second phosphor powder groups 220 comprising the plurality of second phosphorous granules 221 should be considered as a light source with a single color (the second phosphor powder groups 220 are pure light sources).

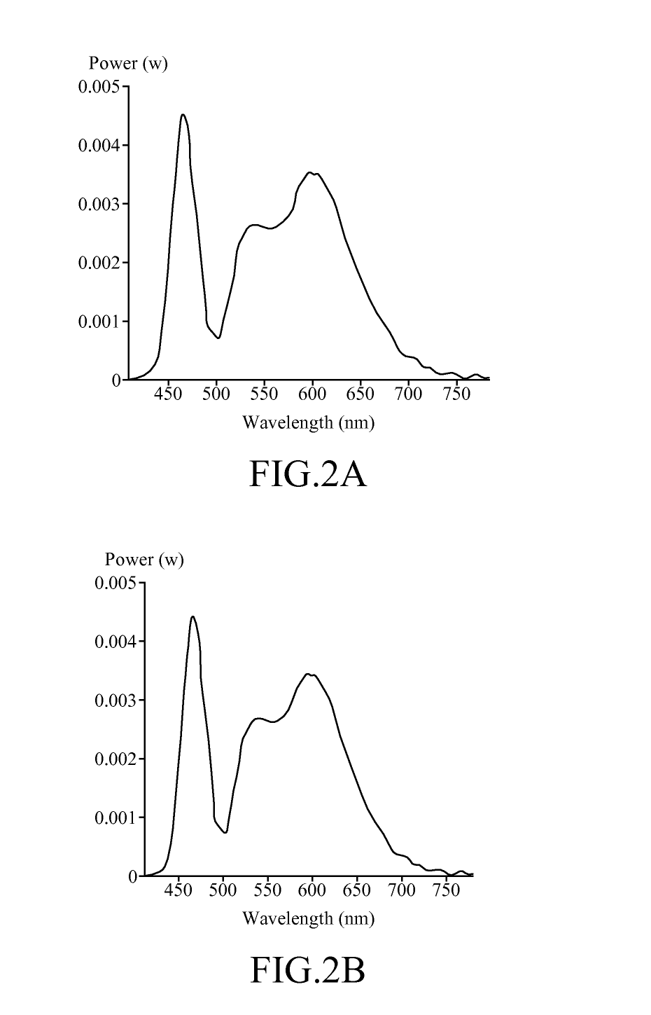

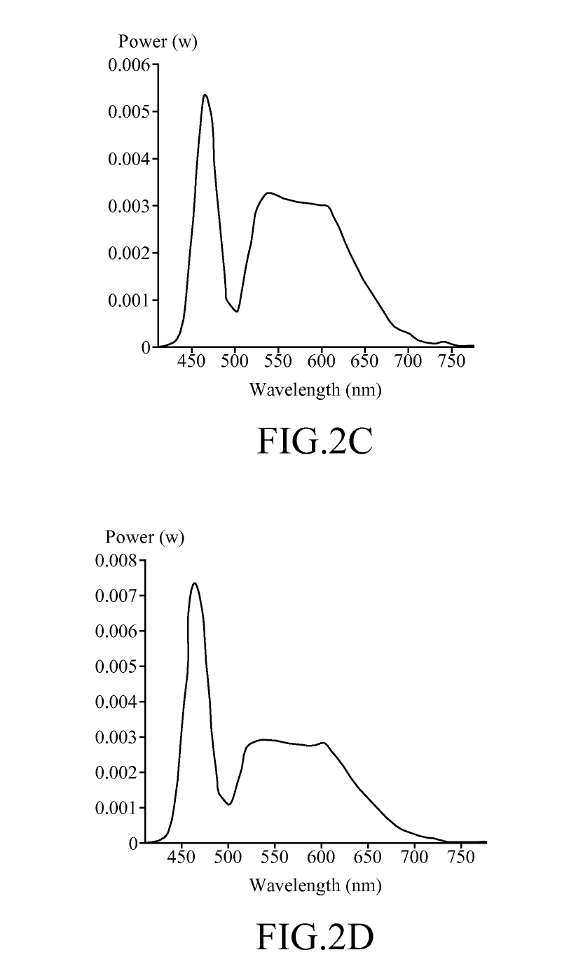

The following compares the luminous efficacy, the color rendering index, and the color temperature of the light-emitting diode chip of Example and Comparative Examples by optical simulations. Please refer to FIG. 2A to FIG. 2D, FIG. 2A is a graph of the relationship between luminous efficacy and the wavelength of the light-emitting diode chip according to an embodiment of the disclosure, FIG. 2B is a graph of the relationship between luminous efficacy and the wavelength of the light-emitting diode chip according to Comparative Example 1 of the disclosure, FIG. 2C is a graph of the relationship between luminous efficacy and the wavelength of the light-emitting diode chip according to Comparative Example 2 of the disclosure, and FIG. 2D is a graph of the relationship between luminous efficacy and the wavelength of the light-emitting diode chip according to Comparative Example 3 of the disclosure.

In the above experiments, the size of the light-emitting diode chips is 40 mils×40 mils.

The results are listed in the following table.

| | | Comparative | Comparative | Comparative |
|---|---|---|---|---|
| | Example | Example 1 | Example 2 | Example 3 |
| Color | 83.83 | 83.51 | 83.92 | 83.02 |
| Rendering | | | | |
| Index | | | | |
| Luminous | 0.64851 | 0.58323 | 0.58376 | 0.61135 |
| efficacy | | | | |
| Color | 6452.8 K | 4100.0 K | 4165.3 K | 4192.9 K |
| Temperature | | | | |

Regarding to Comparative Example 1, a phosphor layer is disposed on an illuminating body, and the phosphor layer comprises two different phosphor powders with different colors. The two different phosphor powders are mixed together. In other words, the light-emitting diode chip of Comparative Example 1 is manufactured by a traditional mixing process which is described in Background. Regarding to Comparative Example 2, a first phosphor layer is disposed on an illuminating body, and a second phosphor layer is disposed on the first phosphor layer. Regarding to Comparative Example 3, the differences between Comparative Example 3 and Example is that the phosphor powder groups of Comparative Example 3 are cubic shape, while the phosphor powder groups of Example are hemispherically-shaped.

Regarding Example, the color rendering index of the light-emitting diode chip is 83.83. The color rendering index of white LED is greater than 80, so that the color rendering index is improved. Regarding to the luminous efficacy, the Example (0.64851) of the disclosure is much greater than Comparative Example 1 (0.58323) and Comparative Example 2 (0.58376). The luminous efficacy of Example is increased by at least 10%, as compared with Comparative Example 1 and Comparative Example 2. In detail, in Example, the secondary excitation between the phosphor powder groups is greatly decreased, so that the luminous efficacy of Example is obviously improved (thus, it's easy to see that the luminous efficacy of Example is improved). In Comparative Example 3, since the phosphor powder groups are cubic, the result of focusing light by Comparative Example 3 is not as good as Example. Therefore, the powders of Comparative Example 3 can not avoid the problem of the secondary excitation. Accordingly, the luminous efficacy of Example (0.64851) is better than the luminous efficacy of Comparative Example 3 (0.61135). The luminous efficacy of Example is increased by at least 5%, as compared with Comparative Example 3. Regarding to the color temperature, the color temperature of Example is 6452.8 K, and Example is a light-emitting diode chip with high color temperature (namely, cold light). However, the light-emitting diode chip having a high color temperature does not limit the disclosure. The color temperature of the light-emitting diode can be adjusted by tuning the ratio of the phosphor powder groups. In some other embodiments, the light-emitting diode chip has a middle color temperature (e.g. 5000 K). In some other embodiments, the light-emitting diode chip has a low color temperature (namely, warm light, e.g. 3000 K).

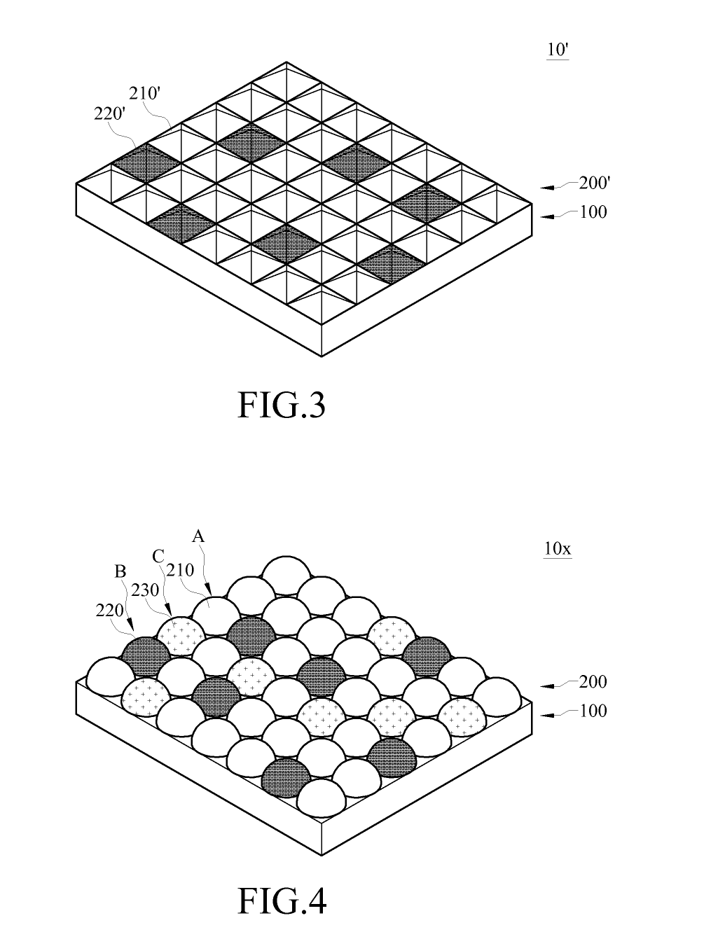

In this and some other embodiments, the shape of the phosphor powder groups being hemispherical does not limit the disclosure. Please refer to FIG. 3; FIG. 3 is a perspective view of part of the light-emitting diode chip according to another embodiment of the disclosure. In FIG. 3, the first phosphor powder groups 210′ and the second phosphor powder groups 220′ of the light-emitting diode chip 10′ are pyramidally-shaped. The pyramidally-shaped first phosphor powder groups 210′ and the pyramidally-shaped second phosphor powder groups 220′ can focus light better. Thus, the pyramidally-shaped powders can decrease or even avoid the problem, which the light emitted by the powders passes through other powders causing the secondary excitation, so that the pyramidally-shaped powders have better luminous efficacy.

In this and some other embodiments, the phosphor powder groups are disposed on fine electroforming modules by a micro-dispensing process (or dispensing process), and then the phosphor powder groups are disposed on the illuminating body or the phosphor layer. Moreover, the fine electroforming molds are hemispherically-shaped or pyramidally-shaped, so that the manufactured phosphor powder groups have a corresponding shape (thus hemispherically-shaped or pyramidally-shaped).

Please refer to FIG. 4; FIG. 4 is a perspective view of part of the light-emitting diode chip according to another embodiment of the disclosure. The embodiment of FIG. 4 is similar to the embodiment of FIG. 1. The differences are that in FIG. 4, the first phosphor layer 200 of the light-emitting diode chip 10x further comprises third phosphor powder groups 230. The third phosphor powder groups 230 are similar to the first phosphor powder groups 210 and the second phosphor powder groups 220, and the differences are that the third phosphor powder groups 230 may have a different emission wavelength from the first phosphor powder groups 210 and the second phosphor powder groups 220. Furthermore, the third phosphor powder groups 230 have a fourth emission wavelength, and the fourth emission wavelength is greater than the first emission wavelength of the illuminating body 100. In addition, the third phosphor powder groups 230 have a plurality of third emitting sections C. The first emitting sections A, the second emitting sections B, and the third emitting sections C are arranged in an array arrangement on the illuminating body 100. Thus, the color rendering index and the luminous efficacy of the light-emitting diode chip 10x are further improved by the third phosphor powder groups emitting light with another wavelength. For example, the light body 100 emits blue light, the first phosphor powder groups 210 emit yellow light, the second phosphor powder groups 220 emit red light, and the third phosphor powder groups 230 emit green light. By mixing the four kinds of light, the light-emitting diode chip 10x is capable of emitting white light, and the color rendering index of the light-emitting diode chip 10x is further improved.

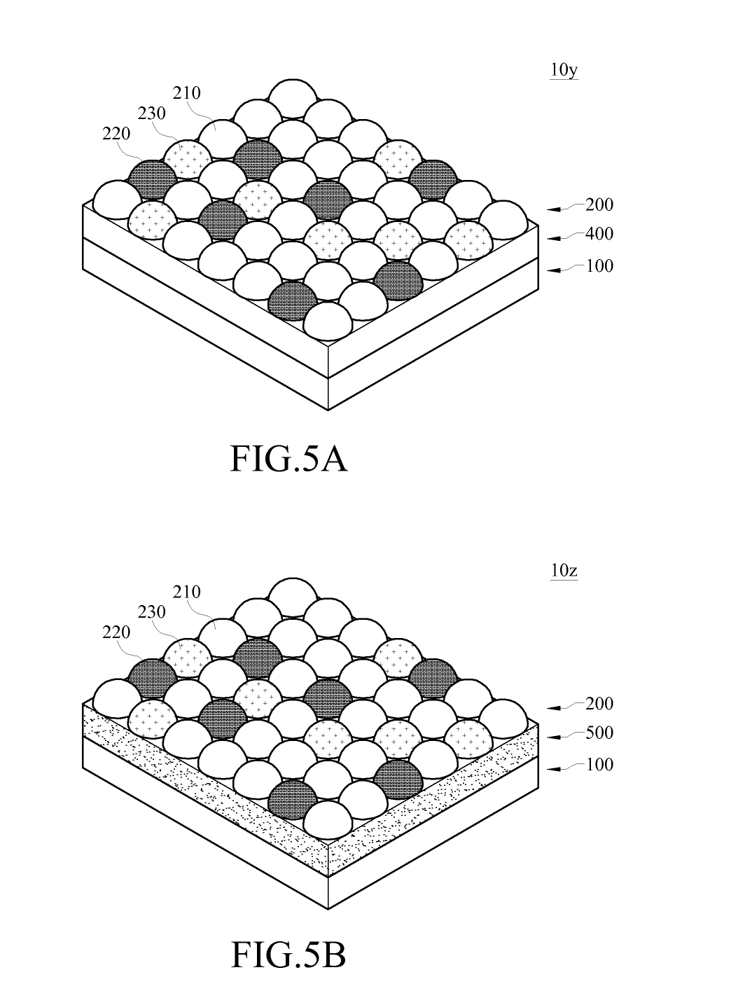

In FIG. 4, the first phosphor powder groups 210, the second phosphor powder groups 220, and the third phosphor powder groups 230 of the first phosphor layer 200 contact with the illuminating body 100, but the disclosure is not limited thereto. Please refer to FIG. 5A and FIG. 5B, FIG. 5A is a perspective view of part of the light-emitting diode chip according to another embodiment of the disclosure, and FIG. 5B is a perspective view of part of the light-emitting diode chip according to another embodiment of the disclosure. The embodiments of FIG. 5A and FIG. 5B are similar to the embodiments of FIG. 1A and FIG. 4. However, the light-emitting diode chip 10y of FIG. 5A further comprises a second phosphor layer 400, and the light-emitting diode chip 10z of FIG. 5B further comprises an adhesive layer 500.

Moreover, in FIG. 5A, the light-emitting diode chip 10y further comprises a second phosphor layer 400, and the second phosphor layer 400 comprises a plurality of fourth phosphor powder groups. The plurality of first phosphor powder groups 210, the plurality of second phosphor powder groups 220, and the plurality of third phosphor powder groups 230 are disposed on the second phosphor layer 400. The second phosphor layer 400 is disposed on the illuminating body 100. In other words, the second phosphor layer 400 is disposed between the first phosphor layer 200 and the illuminating body 100. The fourth phosphor powder groups of the second phosphor layer have a fifth emission wavelength. The first emission wavelength is smaller than the fifth emission wavelength. The fifth emission wavelength may be smaller than, equal to, or greater than the second emission wavelength, the third emission wavelength, and the fourth emission wavelength. Thus, the relative values between the fifth emission wavelength as well as the second emission wavelength, the third emission wavelength, and the fourth emission wavelength does not limit the disclosure. For example, the light body 100 emits blue light, the first phosphor powder groups 210 emit yellow light, the second phosphor powder groups 220 emit red light, the third phosphor powder groups 230 emit green light, and the second phosphor layer 400 emits yellow light, but the disclosure is not limited thereto.

In this embodiment, the second phosphor layer 400 covers the illuminating body 100 completely. Thus, the light-emitting diode chip 10y can prevent the light emitted by the light body 100 from passing through the gaps between the first phosphor powder groups 210, the second phosphor powder groups 220, and the third phosphor powder groups 230. Thus, light leaking from the gaps is avoided and the color rending index of the light-emitting diode chip 10y is further improved. For instance, the illuminating body 100 emits blue light, and part of the light-emitting diode chip 10y would become bluish when the blue light passes through the gaps. Therefore, the design of the second phosphor layer 400 covering the illuminating body 100 completely can further improve the color rendering index of the light-emitting diode chip 10y.

The embodiment in FIG. 5B is similar to the embodiment in FIG. 5A, the differences are that in FIG. 5B, the second phosphor layer 400 is replaced by an adhesive layer 500 in FIG. 5A. In this embodiment, the light-emitting diode chip 10z further comprises an adhesive layer 500, the plurality of first phosphor powder groups 210, the plurality of second phosphor powder groups 220, and the plurality of third phosphor powder groups 230 are disposed on the adhesive layer 500. The adhesive layer 500 is disposed on the illuminating body 100. Therefore, the adhesive layer 500 is disposed between the first phosphor layer 200 and the illuminating body 100. The adhesive layer 500 can further strengthen the structure of the plurality of first phosphor powder groups 210, the plurality of second phosphor powder groups 220, and the plurality of third phosphor powder groups 230 of the first phosphor layer 200 that are disposed on the illuminating body 100. Also, the adhesive layer 500 covers the illuminating body 100 completely. Thus, the light-emitting diode chip 10z can prevent the light emitted by the light body 100 from passing through the gaps between the first phosphor powder groups 210, the second phosphor powder groups 220, and the third phosphor powder groups 230. Thus, light leaking from the gaps is avoided, and the color rending of the light-emitting diode chip 10z is further improved. For instance, the illuminating body 100 emits blue light, and part of the light-emitting diode chip 10z would become bluish after the blue light passes through the gaps. Therefore, the design of the adhesive layer 500 covering the illuminating body 100 can further improve the color rendering index of the light-emitting diode chip 10z.

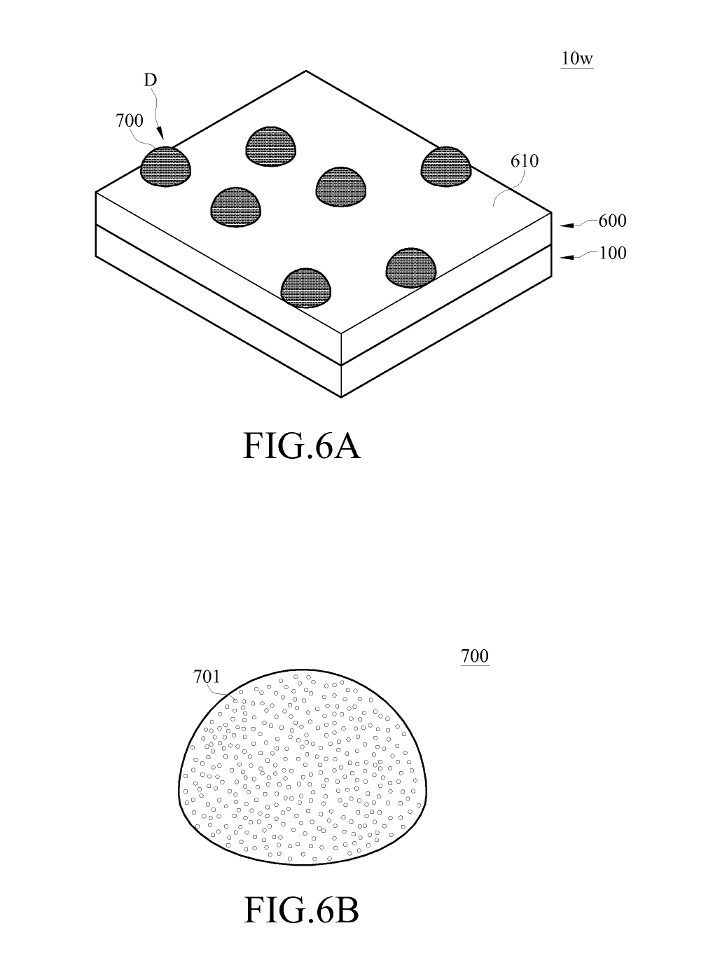

Finally, please refer to FIG. 6A and FIG. 6B. FIG. 6A is a perspective view of part of the light-emitting diode chip according to another embodiment of the disclosure, and FIG. 6B is a schematic diagram of the first phosphor powder groups in FIG. 6A. In the embodiment, the light-emitting diode chip 10w comprises an illuminating body 100, a phosphor layer 600, and a plurality of second phosphor powder groups 700. The phosphor layer 600 is disposed on the illuminating body 100. The phosphor layer 600 comprises a plurality of first phosphor powder groups 610. The second phosphor powder groups 700 are disposed on the phosphor layer 600 separately (thus, the second phosphor powder groups 700 are dispersed on the phosphor layer 600).

The illuminating body 100 has a first emission wavelength. The plurality of first phosphor powder groups 610 has a second emission wavelength. The second phosphor powder groups 700 have a third emission wavelength. The first emission wavelength is smaller than the second emission wavelength, and the second emission wavelength is smaller than the third emission wavelength. The first emitting wavelength represents the wavelength having the greatest illuminating power among the spectrum of the light emitted by the illuminating body 100. The second emitting wavelength represents the wavelength having the greatest illuminating power among the spectrum of the light emitted by the first phosphor powder groups 610. The third emitting wavelength represents the wavelength having the greatest illuminating power among the spectrum of the light emitted by the second phosphor powder groups 700.

In detail, the second phosphor powder groups 700 have a plurality of emitting sections D, and the plurality of emitting sections D is arranged in an array arrangement on the lighting phosphor layer 600. Thus, when the light emitted by the illuminating body 100 passes through the first phosphor powder groups 610 and the second phosphor powder groups 700, the first phosphor powder groups 610 and the second phosphor powder groups 700 emit corresponding light. Therefore, the light emitted by the illuminating body 100, the first phosphor powder groups 610, and the second phosphor powder groups 700 achieves the effect of mixing light.

In this embodiment, the illuminating body 100 emits blue light, the first phosphor powder groups 610 emit yellow light, and the second phosphor powder groups 700 emit red light. By mixing the three kinds of light, the light-emitting diode chip 10w is capable of emitting white light. As compared with previous art, the color rendering index of the light-emitting diode chip 10w is greater. In this and some other embodiments, the second emitting sections D of the second phosphor powder groups are distributed on the illuminating body 100 evenly, so that the luminous quality of the light-emitting diode chip 10w is improved.

Also, the plurality of first phosphor powder groups 610 of the phosphor layer 600 have a first emitting area, and the plurality of second phosphor powder groups 700 have a second emitting area. The first emitting area represents the summation of the emitting area of the plurality of first phosphor powder groups 610. The second emitting area represents the summation of the emitting area of the plurality of second phosphor powder groups 700. In this embodiment, the ratio between the first emitting area of the first phosphor powder groups 610 to the second emitting area of the second phosphor powder groups 700 is between 5:1 and 20:1. A user can adjust the ratio of the first emitting area to the second emitting area according to his/her needs.

In this and some other embodiments, the phosphor layer 600 covers the illuminating body 100 completely. Thus, the light-emitting diode chip 10w can prevent the light emitted by the illuminating body 100 from passing through the gaps between the first phosphor powder groups 610 and the second phosphor powder groups 700. Further, the secondary excitation of the light-emitting diode chip 10w is decreased. Therefore, the luminous efficacy of the light-emitting diode chip 10w is further improved.

The first phosphor powder groups 610 and the second phosphor powder groups 700 are similar to the above embodiments. In other words, the sides of the first phosphor powder groups 610 and the second phosphor powder groups 700, which do not contact with the illuminating body 100, are curved surfaces. The first phosphor powder groups 610 have a contacting surface, which contacts with the illuminating body 100. The second phosphor powder groups 700 have a contacting surface, which contacts with the first phosphor layer 600. The side opposite to the contacting surface of the first phosphor powder groups 610 is a curved surface, and the side opposite to the contacting surface of the second phosphor powder groups 700 is a curved surface. Therefore, the first phosphor powder groups 610 and the second phosphor powder groups 700 can focus light better. For instance, the first phosphor powder groups 610 and the second phosphor powder groups 700 are hemispherically-shaped, but the disclosure is not limited thereto. In some other embodiments, the first phosphor powder groups 610 and the second phosphor powder groups 700 are pyramidally-shaped.

In detail, the second phosphor powder groups 700 have a plurality of phosphorous granules 701 and, for example, adhesive agents. The adhesive agents are able to strengthen the structure of the second phosphor powder groups 700. In this and some other embodiments, the emitting wavelength of each of the plurality of phosphorous granules 701 is the same or similar. In other words, the second phosphor powder groups 700 comprising the plurality of phosphorous granules 701 should be considered as a light source with a single color.

According to the light-emitting diode chip of the disclosure, the first phosphor layer is disposed on the illuminating body, the first phosphor powder groups and the second phosphor powder groups are in the first phosphor layer, as well as the phosphor powder groups do not overlap each other. Therefore, when the phosphor powder groups illuminate light, the light emitted by the phosphor powder groups do not pass through other phosphor powder groups. Thus, the decreasing of the luminous efficacy due to the secondary excitation is greatly reduced or avoided. Therefore, the light-emitting diode chip of the embodiment has a greater color rendering index and greater luminous efficacy. The light-emitting diode chip of the embodiment can be applied in fields requiring a high luminous quality, such as medical illuminating or art illuminating, and the light-emitting diode chip has more applications.

According to other light-emitting diode chips of the disclosure, the second phosphor powder groups are disposed on the phosphor layer separately. Therefore, the light emitted by the first phosphor powder groups of the phosphor layer being absorbed by the second phosphor powder groups is decreased, and the secondary excitation between the phosphor powder groups is lowered.

In addition, since the sides, which do not contact with the illuminating body, of the phosphor powder groups (opposite to the contacting surface) are curved surfaces, the phosphor powder groups can focus light better. When the phosphor powder groups emit light, the light passing through other phosphor powder groups nearby is decreased or is even avoided. Therefore, the secondary excitation of the light-emitting diode chip is decreased or is even avoided. Thus, luminous efficacy of the light-emitting diode chip is further improved.

In addition, in some embodiments, the first phosphor layer of the light-emitting diode chip comprises the first phosphor powder groups, the second phosphor powder groups, and the third phosphor powder groups. Therefore, the light-emitting diode chip has a better effect of mixing light by mixing the four kinds of light, and the color rendering index of the light-emitting diode chip is further improved.

In addition, in some embodiments, the light-emitting diode chip further comprises a second phosphor layer or an adhesive layer between the illuminating body and the first phosphor layer of the light-emitting diode chip, and the second phosphor layer or the adhesive layer covers the illuminating body completely. Therefore, the light-emitting diode chip can prevent the light emitted by the light body from passing through the gaps between the phosphor powder groups, so that the color rending of the light-emitting diode chip is further improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting diode chip, comprising: an illuminating body, having a first emission wavelength; and
a first phosphor layer, disposed on the illuminating body, the first phosphor layer comprising a plurality of first phosphor powder groups and a plurality of second phosphor powder groups, the plurality of first phosphor powder groups having a second emission wavelength, and the second phosphor powder groups having a third emission wavelength;
wherein, the first wavelength is smaller than the second emission wavelength, and the second emission wavelength is smaller than the third emission wavelength.

2. The light-emitting diode chip according to claim 1, wherein both the plurality of first phosphor powder groups and the second phosphor powder groups of the first phosphor layer contact with the illuminating body.

3. The light-emitting diode chip according to claim 1, wherein the plurality of first phosphor powder groups of the first phosphor layer have a plurality of first emitting sections, the plurality of second phosphor powder groups of the first phosphor layer have a plurality of second emitting sections, and the plurality of first emitting sections and the plurality of second emitting sections are arranged in an array arrangement on the illuminating body.

4. The light-emitting diode chip according to claim 1, wherein the plurality of first phosphor powder groups of the first phosphor layer have a first emitting area, the plurality of second phosphor powder groups of the first phosphor layer have a second emitting area, and the ratio of the first emitting area to the second area is between 5:1 and 20:1.

5. The light-emitting diode chip according to claim 1, wherein the sides of the plurality of first phosphor powder groups and the plurality of second phosphor powder groups of the first phosphor layer not contacting with the illuminating body have a curved surface.

6. The light-emitting diode chip according to claim 1, wherein the plurality of first phosphor powder groups and the plurality of second phosphor powder groups of the first phosphor layer are hemispherically-shaped or pyramidally-shaped.

7. The light-emitting diode chip according to claim 1, wherein the first phosphor layer further comprises a plurality of third phosphor powder groups, the plurality of third phosphor powder groups have a fourth emission wavelength, and the first emission wavelength is smaller than the fourth emission wavelength.

8. The light-emitting diode chip according to claim 1, further comprising a second phosphor layer, the second phosphor layer comprising a plurality of fourth phosphor powder groups, wherein the plurality of first phosphor powder groups of the first phosphor layer and the plurality of second phosphor powder groups of the first phosphor layer are disposed on the second phosphor layer, the second phosphor layer is disposed on the illuminating body, the plurality of fourth phosphor powder groups have a fifth emission wavelength, and the first emission wavelength is smaller than the fifth emission wavelength.

9. The light-emitting diode chip according to claim 1, further comprising an adhesive layer disposed on the illuminating body, and wherein the plurality of first phosphor powder groups of the first phosphor layer and the plurality of second phosphor powder groups of the first phosphor layer are disposed on the adhesive layer.

10. A light-emitting diode chip, comprising:
an illuminating body, having a first emission wavelength;
a phosphor layer, disposed on the illuminating body, the first phosphor layer comprising a plurality of first phosphor powder groups, and the plurality of first phosphor powder groups having a second emission wavelength; and
a plurality of second phosphor powder groups, disposed on the phosphor layer separately, and the plurality of second phosphor powder groups having a third emission wavelength;
wherein, the first wavelength is smaller than the second emission wavelength, and the second emission wavelength is smaller than the third emission wavelength.

11. The light-emitting diode chip according to claim 10, wherein the plurality of second phosphor powder groups have a plurality of emitting sections, and the plurality of emitting sections are arranged in an array arrangement on the phosphor layer.

12. The light-emitting diode chip according to claim 10, wherein the phosphor layer has a first emitting area, the plurality of second phosphor powder groups have a second emitting area, and the ratio of the first emitting area to the second area is between 5:1 and 20:1.

13. The light-emitting diode chip according to claim 10, wherein the sides of the plurality of second phosphor powder groups not contacting with the illuminating body have a curved surface.

14. The light-emitting diode chip according to claim 10, wherein the plurality of second phosphor powder groups of the first phosphor layer are hemispherically-shaped or pyramidally-shaped.
